(19) United States
(12) Patent Application Publication
(10) Pub. No.: US 2023/0341783 A1
(43) Pub. Date: Oct. 26, 2023

(54) DETERMINING LITHOGRAPHIC MATCHING PERFORMANCE

(71) Applicant: ASML NETHERLANDS B.V., Veldhoven (NL)

(72) Inventors: Arnaud HUBAUX, Erpent (BE); Patrick WARNAAR, Tilburg (NL); Scott Anderson MIDDLEBROOKS, Duizel (NL); Tijmen Pieter COLLIGNON, Eindhoven (NL); Chung-Hsun LI, Eindhoven (NL); Georgios TSIROGIANNIS, Eindhoven (NL); Sayyed Mojtaba SHAKERI, Geldrop (NL)

(73) Assignee: ASML NETHERLANDS B.V., Veldhoven (NL)

(21) Appl. No.: 17/796,434

(22) PCT Filed: Jan. 19, 2021
(86) PCT No.: PCT/EP2021/051002

§ 371 Date: Jul. 29, 2022

(30) Foreign Application Priority Data
Feb. 14, 2020 (EP) 20157301.1
May 26, 2020 (EP) 20176415.6

(51) Int. Cl. G03F 7/00

(52) U.S. Cl. CPC G03F 7/705; G03F 7/70458; G03F 7/70633

(57) ABSTRACT

A method of determining matching performance between tools used in semiconductor manufacture and associated tools is described. The method includes obtaining a plurality of data sets related to a plurality of tools and a representation of the data sets in a reduced space having a reduced dimensionality. A matching metric and/or matching correction is determined based on matching the reduced data sets in the reduced space.

### CROSS-REFERENCE TO RELATED APPLICATIONS

This application claims priority of EP application 20157301.1 which was filed on 14 Feb. 2020 and EP application 20176415.6 which was filed on 26 May 2020 which are incorporated herein in its entirety by reference.

### FIELD

The present invention relates to methods of determining lithographic matching performance between lithographic apparatuses for semiconductor manufacture, a semiconductor manufacturing processes, a lithographic apparatus, a lithographic cell and associated computer program products.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm deep ultraviolet (DUV), 193 nm deep ultraviolet (DUV) and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a DUV lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k₁.

Cross-platform, for example DUV to EUV, matching performance between lithographic apparatuses is vital for on-product overlay performance. Conventionally, this is achieved using a dedicated verification test. This test requires certain machine setup procedure as a pre-requisite that takes hours of time. Extra scanner and metrology time is required for pre-setup, exposure and overlay measurement. The test is performed only when it is very necessary and therefore cannot be used for daily monitoring purposes, which is necessary for high-volume manufacturing.

### SUMMARY

It is desirable to provide a method of determining lithographic matching performance between lithographic apparatuses that solves the above-discussed problem.

Embodiments of the invention are disclosed in the claims and in the detailed description.

In a first aspect of the invention there is provided a method of determining matching performance between tools used in semiconductor manufacture, the method comprising: obtaining a plurality of data sets related to a plurality of tools, obtaining a representation of said data sets in a reduced space having a reduced dimensionality; and determining a matching metric and/or matching correction based on matching said reduced data sets in the reduced space.

In a second aspect of the invention there is provided a semiconductor manufacturing process comprising a method for determining lithographic matching performance according to the first aspect.

In a third aspect of the invention there is provided a lithographic apparatus comprising:
an illumination system configured to provide a projection beam of radiation;
a support structure configured to support a patterning device, the patterning device configured to pattern the projection beam according to a desired pattern;
a substrate table configured to hold a substrate;
a projection system configured the project the patterned beam onto a target portion of the substrate; and
a processing unit configured to determine lithographic matching performance according to the method of the first aspect.

In a fourth aspect of the invention there is provided a computer program product comprising machine readable instructions for causing a general-purpose data processing apparatus to perform the steps of a method according to the first aspect.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is a flowchart of a decision making method;

FIG. 5 is a schematic overview of control mechanisms in a lithographic process utilizing a scanner stability module;

FIG. 6 depicts a schematic overview of normal operation of a set of DUV and EUV lithographic apparatuses with recurrent monitoring for stability control;

FIG. 7 depicts the problem of unavailability of a lithographic apparatus, necessitating cross-platform lithographic matching;

FIG. 8 depicts a test for determining cross-platform lithographic matching performance using a conventional approach;

FIG. 9 comprises three plots relating to a common timeframe: FIG. 9(a) is a plot of raw parameter data, more specifically reticle align (RA) data, against time t; FIG. 9(b) is an equivalent non-linear model function mf derived according to a method of an embodiment of the invention; and FIG. 9(c) comprises the residual Δ between the plots of FIG. 9(a) and FIG. 9(b), illustrating a categorical indicator according to a method of an embodiment of the invention;

FIG. 10 is a schematic diagram of an encoder/decoder network used in embodiments of the present invention;

FIG. 11 is a flowchart of an embodiment according to a third main embodiment of the invention;

FIG. 12a,b,c and d conceptually illustrate the concepts of clustering and manifold learning;

FIG. 13a,b and c conceptually illustrate a production monitoring application of the basic method of FIG. 11; and

FIG. 14 depicts a block diagram of a computer system for controlling a system and/or method as disclosed herein.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

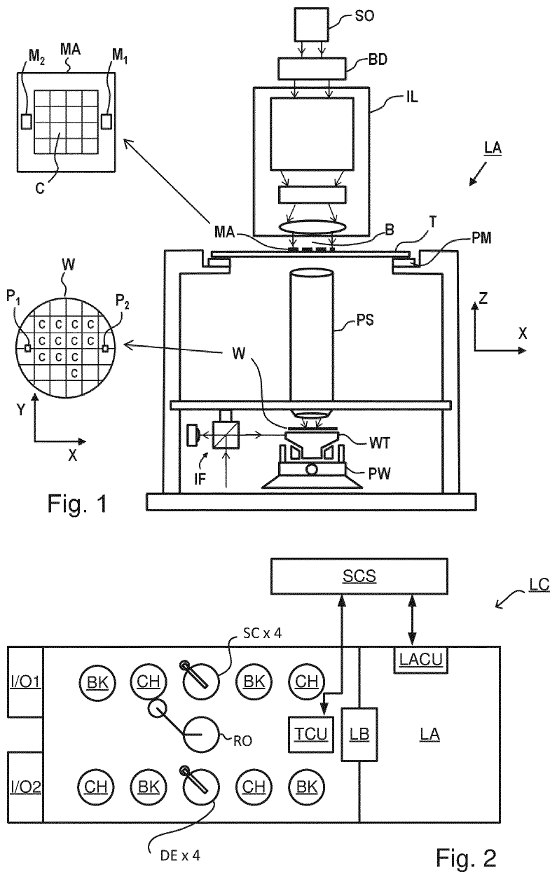

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

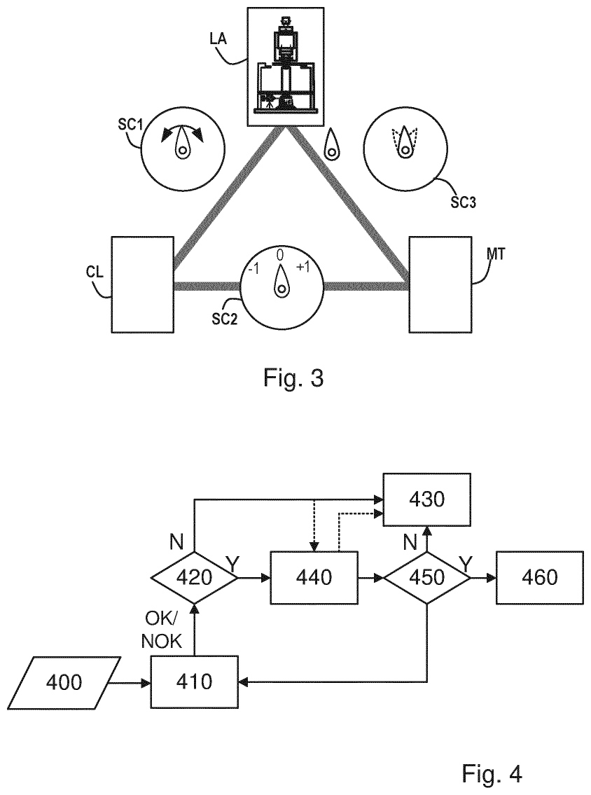

Typically, the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

As such, the proposed method comprises making a decision as part of a manufacturing process, the method comprising: obtaining scanner data relating to one or more parameters of a lithographic exposure step of the manufacturing process; deriving a categorical indicator from the scanner data, the categorical indicator being indicative of a quality of the manufacturing process; and deciding on an action based on the categorical indicator. Scanner data relating to one or more parameters of a lithographic exposure step may comprise data produced by the scanner itself, either during or in preparation of the exposure step, and/or generated by another station (e.g., a stand-alone measuring/alignment station) in a preparatory step for the exposure. As such, it does not necessarily have to be generated by or within the scanner. The term scanner is used generally to describe any lithographic exposure apparatus.

FIG. 4 is a flowchart describing a method for making a decision in a manufacturing process utilizing a fault detection and classification (FDC) method/system. Scanner data 400 is generated during exposure (i.e., exposure scanner data), or following a maintenance action (or by any other means). This scanner data 400, which is numerical in nature, is fed into the FDC system 410. The FDC system 410 converts the data into functional, scanner physics-based indicators and aggregates these functional indicators according to the system physics, so as to determine a categorical system indicator for each substrate. The categorical indicator could be binary, such as whether they meet a quality threshold (OK) or not (NOK). Alternatively there may be more than two categories (e.g., based on statistical binning techniques).

A check decision 420 is made to decide whether a substrate is to be checked/inspected, based on the scanner data 400, and more specifically, on the categorical indicator assigned to that substrate. If it is decided not to check the substrate, then the substrate is forwarded for processing 430. It may be that a few of these substrates still undergo a metrology step 440 (e.g., input data for a control loop and/or to validate the decision made at step 420). If a check is decided at step 420, the substrate is measured 440, and based on the result of the measurement, a rework decision 450 is made, to decide whether the substrate is to be reworked. In another embodiment, the rework decision is made based directly on the categorical quality value determined by FDC system 410 without the check decision. Depending on the result of the rework decision, the substrate is either reworked 460, or deemed to be OK and forwarded for processing 430. If the latter, this would indicate that the categorical indicator assigned to that substrate was incorrect/inaccurate. Note that the actual decisions illustrated (check and/or rework) are only exemplary, and other decisions could be based on the categorical values/advice output from the FDC, and/or the FDC output could be used to trigger an alarm (e.g., to indicate poor scanner performance). The result of the rework decision 450 for each substrate is fed back to the FDC system 410. The FDC system can use this data to refine and validate its categorization and decision advice (the categorical indicator assigned). In particular, it can validate the assigned categorical indicator against the actual decision and, based on this, make any appropriate changes to the categorization criteria. For example, it can alter/set any categorization thresholds based on the validation. As such, all the rework decisions made by the user at step 450 should be fed back so that all check decisions of the FDC system 410 are validated. In this way, the categorical classifier within the FDC system 410 system is constantly trained during production, such that it receives more data and therefore becomes more accurate over time

A scanner yields numerical scanner or exposure data, which comprises the numerous data parameter or indicators generated by the scanner during exposure. This scanner data may comprise, for example, any data generated by the scanner which may have an impact on the decision on which the FDC system will advise. For example, the scanner data may comprise measurement data from measurements routinely taken during (or in preparation for) an exposure, for example reticle and or wafer alignment data, leveling data, lens aberration data, any sensor output data etc. The scanner data may also comprise less routinely measured data (or estimated data), e.g., data from less routine maintenance steps, or extrapolated therefrom. A specific example such data may comprise source collector contamination data for EUV systems. The FDC system derives numerical functional indicators based on the scanner data. These functional indicators may be trained on production data so as to reflect actual usage of the scanner (e.g., temperature, exposure intervals etc.). The functional indicators can be trained, for example, using statistical, linear/non-linear regression, deep learning or Bayesian learning techniques. Reliable and accurate functional indicators may be constructed, for example, based on the scanner parameter data and the domain knowledge, where the domain knowledge may comprise a measure of deviation of the scanner parameters from nominal. Nominal may be based on known physics of the system/process and scanner behavior.

Models which link these indicators to on-product categorical indicators can then be defined. The categorization can be binary (e.g., OK/NOK) or a more advanced classification based on measurement binning or patterns. The link models tie the physics driven functional indicators to observed on-product impact for specific user applications and way of working. The categorical indicators aggregate the functional indicators according to the physics of the system. There may be two or more levels or hierarchies of categorical indicators, each for a particular error contributor. For example, a first level may comprise overlay contributors (e.g., a reticle align contributor to X direction intra-field overlay, a reticle align contributor to Y direction inter-field overlay, a leveling contributor to inter-field CD, etc. A second level of categorical indicators may aggregate the first level categorical indicators (e.g., in terms of direction and/or in terms of inter-field versus intra-field for overlay and/or in terms of inter-field versus intra-field for CD. These may be aggregated further in a third level: e.g., overlay OK/NOK and/or a CD OK/NOK. The categorical indicators mentioned above are purely for example, and any suitable alternative indicators may be used. These indicators can then be used to provide advice and/or make process decisions, such as whether to inspect and/or rework a substrate.

The categorical indicators may be derived from models/simulators based on machine learning techniques. Such a machine learning model can be trained with historical data (prior indicator data) labeled according to its appropriate category (i.e., should it be reworked). The labeling can be based on expert data (e.g., from user input) and/or (e.g., based on) measurement results, such that the model is taught to provide effective and reliable prediction of substrate quality based on future numerical data inputs from scanner data. The system categorical indicator training may use, for example, feedforward neural network, random forest, and/or deep learning techniques. Note that the FDC system does not need to know about any user sensitive data for this training; only a higher-level categorization, tolerance and/or decision (e.g., whether or not a substrate would be reworked) is required.

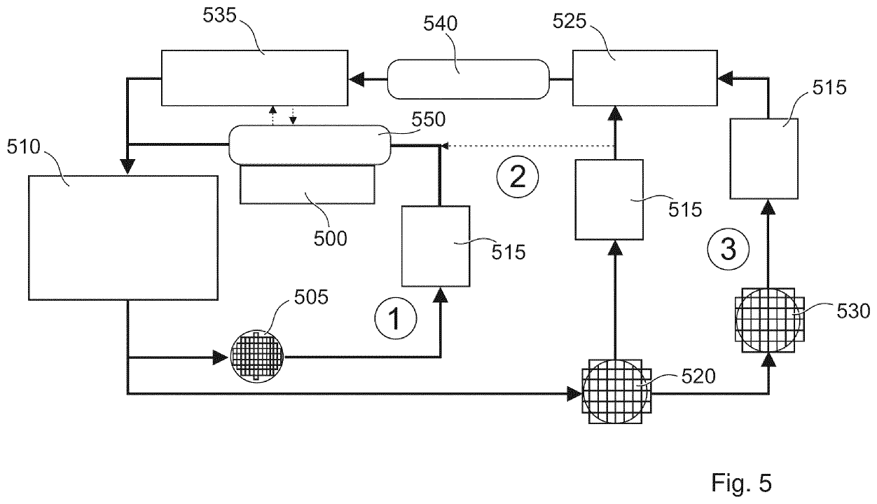

FIG. 5 depicts the overall lithography and metrology method incorporating a stability module 500 (essentially an application running on a server, in this example). Shown are three main process control loops, labeled 1, 2, 3. The first loop provides recurrent monitoring for stability control of the lithography apparatus using the stability module 500 and monitor wafers. A monitor wafer (MW) 505 is shown being passed from a lithography cell 510, having been exposed to set the baseline parameters for focus and overlay. At a later time, metrology tool (MT) 515 reads these baseline parameters, which are then interpreted by the stability module (SM) 500 so as to calculate correction routines so as to provide scanner feedback 550, which is passed to the main lithography apparatus 510, and used when performing further exposures. The exposure of the monitor wafer may involve printing a pattern of marks on top of reference marks. By measuring overlay error between the top and bottom marks, deviations in performance of the lithographic apparatus can be measured, even when the wafers have been removed from the apparatus and placed in the metrology tool.

The second (APC) loop is for local scanner control on-product (determining focus, dose, and overlay on product wafers). The exposed product wafer 520 is passed to metrology unit 515 where information relating for example to parameters such as critical dimension, sidewall angles and overlay is determined and passed onto the Advanced Process Control (APC) module 525. This data is also passed to the stability module 500. Process corrections 540 are made before the Manufacturing Execution System (MES) 535 takes over, providing control of the main lithography apparatus 510, in communication with the scanner stability module 500.

The third control loop is to allow metrology integration into the second (APC) loop (e.g., for double patterning). The post etched wafer 530 is passed to metrology unit 515 which again measures parameters such as critical dimensions, sidewall angles and overlay, read from the wafer. These parameters are passed to the Advanced Process Control (APC) module 525. The loop continues the same as with the second loop.

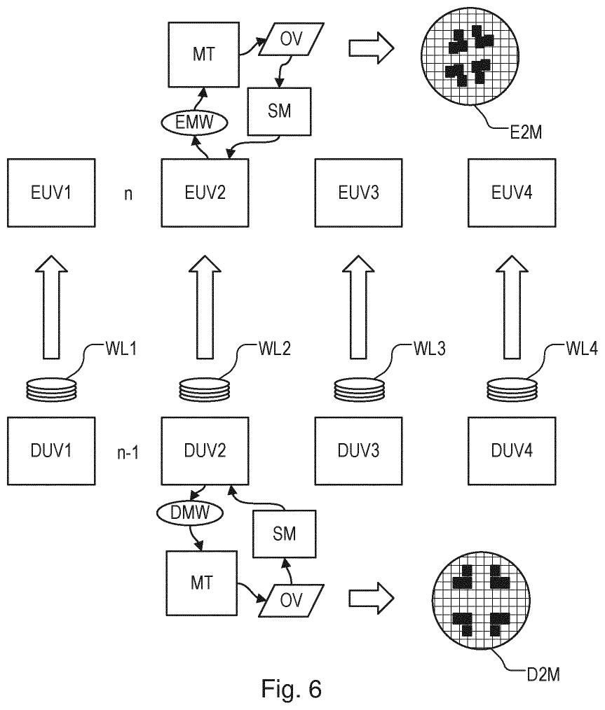

FIG. 6 depicts a schematic overview of normal operation of a set of lithographic apparatuses with recurrent monitoring for stability control. In the examples given below, the lithographic apparatuses are scanners. Four deep UV scanners DUV1 to DUV4 are shown having processed four wafer lots WL1 to WL4 at a lithographic exposure step n-1. These wafer lots are then processed in the next lithographic exposure step n in four extreme UV scanners EUV1 to EUV4. The wafer lots have dedicated routes. For example a wafer lot WL1 exposed in a deep UV scanner DUV1 and then exposed in an extreme UV scanner EUV1.

Each scanner has a process for recurrent monitoring for stability control, as described with reference to FIG. 5. Monitoring data are obtained by measuring one or more monitoring substrates periodically processed on the respective lithographic apparatus. In FIG. 6, for example, an extreme UV Scanner EUV2 processes a monitor wafer EMW which is measured in a metrology tool MW which outputs overlay measurements OV to a stability module SM. The overlay measurements OV are recorded as an wafer map E2M comprising a grid of overlay measurements (which may be represented as overlay residuals). Thus, first monitoring data E2M is obtained from recurrent monitoring for stability control of a first lithographic apparatus EUV2. The first monitoring data E2M are in a first layout. For example, each datum has a particular location on the substrate where it was measured. Also, depicted in this example, a deep UV scanner DUV2 processes a monitor wafer DMW which is measured in a metrology tool MW which outputs overlay measurements OV to a stability module SM. The overlay measurements OV are recorded as an wafer map D2M comprising a grid of overlay measurements. Thus, second monitoring data D2M is obtained from recurrent monitoring for stability control of a second lithographic apparatus DUV2. The second monitoring data D2M are in a second layout, different from the first layout. This difference comes from different layout and density of the features on the monitor wafers EMW and DMW and differences in the sample schemes for overlay measurement. This is to be expected with different platforms such as DUV and EUV.

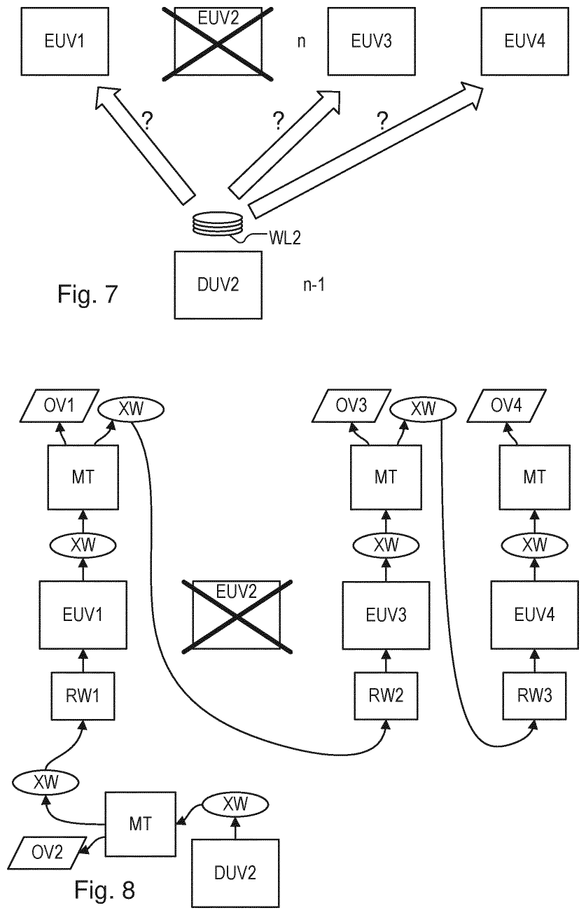

FIG. 7 depicts the problem of unavailability of a lithographic apparatus, necessitating cross-platform lithographic matching. Selected scanners are shown from FIG. 6. One of the EUV scanners EUV2 is not available for production, perhaps because it is down for preventive maintenance. Therefore, the question arises: Where should the wafer lot WL2 from the second DUV scanner DUV2 be processed next? Which of the available EUV scanners EUV1, EUV3 or EUV4 should be used? The answer can be found by determining which of the EUV scanners has the best overlay matching performance with the DUV scanner DUV2.

FIG. 8 depicts determining cross-platform lithographic matching performance using a conventional approach. A cross-platform test wafer XW is exposed on the second DUV scanner DUV2 and metrology tool MT measures the overlay OV2. The test wafer XW is reworked RW1 and exposed in the first EUV tool EUV1. Next, the metrology tool MT measures the overlay OV1. The test wafer XW is reworked RW2 and exposed in the third EUV tool EUV3. The metrology tool MT then measures the overlay OV3. Finally, The test wafer XW is reworked RW3 and exposed in the fourth EUV tool EUV4. The metrology tool MT then measures the overlay OV4. The cross-platform overlay matching performance between the second DUV scanner DUV2 and the first EUV scanner EUV1 is determined by calculating the difference between the respective overlay measurements OV2 and OV1. This is repeated for each of the remaining EUV scanners (i.e. OV2-OV3 and OV2-OV4). The differences are ranked and the EUV scanner with the smallest difference is determined to have the best overlay matching performance. Then the wafer lot WL2 is routed through that scanner. The dedicated verification test described with reference to FIG. 8 requires a scanner setup procedure as a pre-requisite that takes hours of time. It is performed only when it is very necessary and therefore cannot be used for daily monitoring purposes, which is necessary for a high-volume manufacturing environment.

Other known matching methods, which use the outputs from recurrent monitoring for stability control (drift control, DC), such as described in relation to FIG. 5. Such methods require a very sophisticated model is required to extract the correct parameters from each calibration data-set and to map these onto scanner parameters. Any change in scanner capabilities requires an elaborate change in this model. Any error contribution which is not part of the model could potentially introduce unwanted drifts between systems.

To address one or more of these issues, an improved matching method is proposed. Such a method comprises: obtaining a plurality of data sets related to a plurality of tools, obtaining a model configured to represent said data sets as reduced data sets in a reduced space comprising a reduced dimensionality; and determining a matching metric based on matching said reduced data sets in the reduced space.

Three main embodiment will be described, a first physics-based approach and second and third data-driven approaches. The first approach is based, in part, on the FDC system of FIG. 4, and in particular on the functional indicators derived therefor.

This embodiment is based on the fact that the scanner functional indicators are related to scanner data (e.g., alignment data/leveling data/lens data/etc.) using physics/domain knowledge. The relationship of the various functional indicators or a functional fingerprint defined therefrom is scanner and product specific (trained). The functional indicators or fingerprints are represented in a reduced (or latent) feature space such that similar scanners appear as clusters in this feature space.

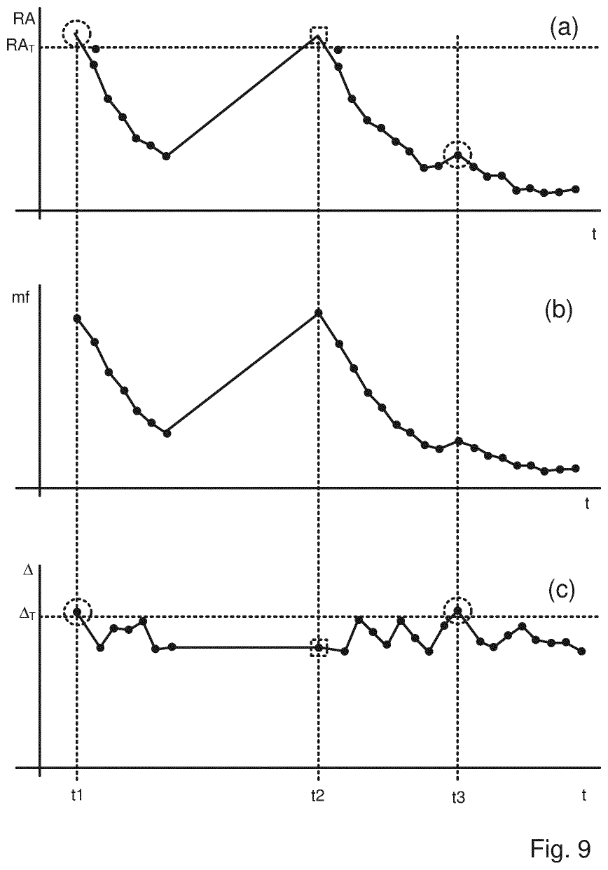

FIG. 9 comprise three plots which illustrate the deriving of the functional (and categorical) indicators, and their effectiveness over the statistical indicators used presently. FIG. 9(a) is a plot of raw parameter data, more specifically reticle align (RA) against time t. The raw parameter data may relate to any parameter of the scanner and/or lithographic process. FIG. 9(b) is an equivalent (e.g., for reticle align) non-linear model function (or fit) mf derived according to methods described herein. As described, such a model can be derived from knowledge of the scanner physics, and can further be trained on production data (e.g., in this specific case, reticle align measurements performed when performing a specific manufacturing process of interest). The training of this model may use statistical, regression, Bayesian learning or deep learning techniques, for example. FIG. 9(c) comprises the residual Δ between the plots of FIG. 9(a) and FIG. 9(b) which can be used as the functional indicator of the methods disclosed herein. One or more thresholds ΔT can be set and/or learned (e.g., initially based on user knowledge/expert opinion and/or training as described), thereby providing a categorical indicator. In particular, the threshold(s) ΔT is/are learned by categorical classifier block 430 (FIG. 4) during the training phase which trains the categorical classifier. It may be that these threshold values are actually unknown or hidden (e.g., when implemented by a neural network). Categorical indicators may relate to one or more of overlay, focus, critical dimension, critical dimension uniformity, for example (e.g., OK/NOK based on which side of the threshold a value is, although non-binary categorical indicators are also possible and envisaged).

It is instructive to compare this to the statistical control technique which is typically employed on the raw data at present. Setting a statistical threshold RAT to the raw data of FIG. 9(a) will result in the outlier at time t1 being identified, but not that at time t3. Furthermore, it will incorrectly identify the point at time t2 as an outlier, when in fact it is not (i.e., it is OK) according to the categorical indicator disclosed herein (illustrated in FIG. 9(c)).

The functional indicators may be defined along the life of the wafer within the scanner and/or other tool (e.g., from loading, measurement (alignment/leveling etc.), exposure etc. As such, raw data relating to a plurality of scanner and process parameters can be treated in the same manner as that illustrated in FIG. 9 to obtain functional indicators for each one, where the functional indicators comprise a residual (e.g., over time) with respect to an expected, nominal or average behavior. These functional indicators can be combined and/or aggregated per tool (and/or per process) to obtain a scanner functional fingerprint comprising a model which functionality defines the on-product performance of the scanner.

In particular, semi-supervised machine learning techniques may be applied to the functional indicators to identify the scanner functional fingerprint. Such fingerprints will be different per scanner, and optionally per product and layer. By inspecting the different indicators through the life of the wafer, expert rules can also determine the most critical matching functional indicators to use (i.e., determining which functional indicators are more relevant for matching), and/or the variations most likely caused by the process, hence should not be used for scanner matching.

The functional indicators or functional fingerprints can then be ranked; e.g., according to their similarity to a tool of interest such as a tool being matched to (e.g., for a successive layer) or a tool being replaced. As such, should there be a requirement to match (or replace) a machine with another, the other machines may be ranked in order of their proximity to the machine being matched or replaced in the reduced (or latent) space in which the functional indicators or fingerprints are represented (e.g., based on a measure of similarity of the functional indicators or functional fingerprints).

A (e.g., unsupervised or semi-supervised) machine learning method, such as a clustering algorithm or similar, may be applied to the scanner fingerprint data or functional indicators, within the reduced or latent feature space (reduced and latent feature space are used interchangeably in this document). Such a clustering algorithm can learn a “normal” region (e.g., describing nominal or average scanner behavior) which has a high density of data points. In this reduced space, the distance or other matching metric between tools/scanner is indicative of how well matched the machines are.

In one embodiment, the trained models and decision working framework such as described in relation to FIG. 4 may be used in the scanner matching and/or scanner selection, for example to validate the result of the method just described, or as an alternative to it. The method may comprise using the (e.g., scanner specific) classifier (e.g., a neural network) trained to predict the per-wafer performance categorically based on the scanner functional indicators. For example, lots which were exposed on a first scanner can be run through the FDC engine related to a second scanner being evaluated to determine whether it is well matched to the first scanner. The FDC engine can return a failure probability prediction per inspection type for this scanner combination. The difference between the predictions (percentage likelihood) combined with functional indicator values can provide further insight on the expected on-product performance matching. By repeating the process over multiple lots, statistical information can be gathered.

For example, if a scanner is unavailable, recent data from that scanner can be translated to a series of functional indicators (e.g., using methods already described in relation to FIG. 4). The functional indicators can be inputted to a neural network associated with (e.g., trained for) a different scanner and the resultant categorical indicator may be compared to the value associated with the scanner which is unavailable. Where the categorical indicators are matched or show a high correlation, it may be concluded that the scanners are well matched.

By combining the results of the expert rules, semi-supervised learning and statistical comparison, it is possible to identify for a given product, layer and scanner, the best matching scanner(s) for the same product and layer.

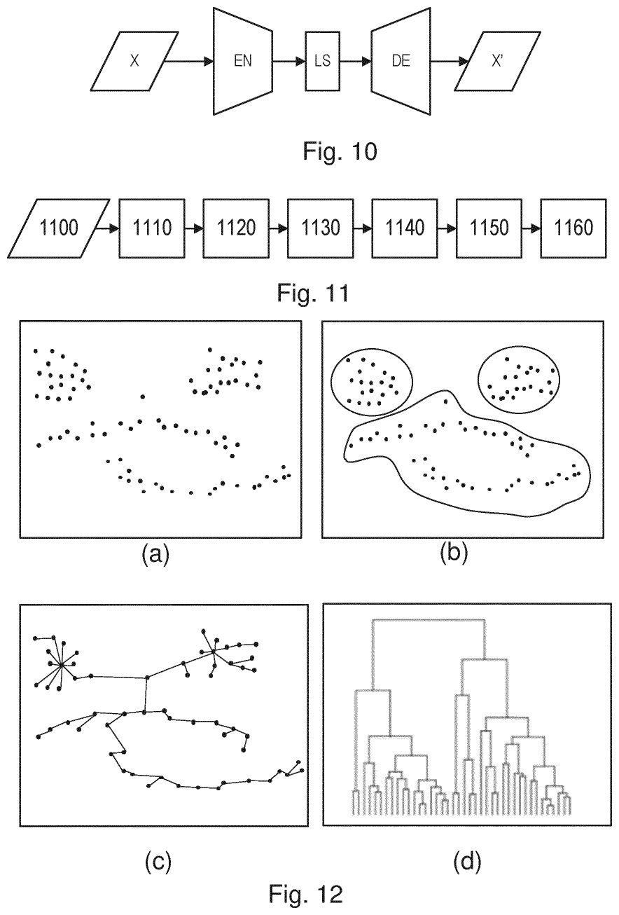

A more data-driven approach will now be described in conjunction with FIG. 10. The method uses an encoder-decoder network, in which the encoder EN encodes input data x into a reduced space or latent space representation LS and the decoder DE decodes the latent space representation back to the original data or close approximation thereof x′ (assuming that it is sufficiently trained). The matching can then be performed within the latent space LS; e.g., the latent space may comprise a vector representation and the matching performed by means of a (n-dimensional) vector comparison.

The model is typically trained on historic scanner data sets for multiple scanner platforms. By inputting data of multiple scanners (scanner ID being a feature) the model allows assessment of the similarity between scanners based on their position within the latent space. Therefore, the tools can be ranked; e.g., according to their similarity (proximity in the latent space) to a tool of interest such as the tool being matched to or the tool being replaced.

The methods may also be used to determine a (matching) correction based on choosing a reference within the latent space (e.g., an average of the tool data represented therein), determine the vector displacement of a tool of interest to this reference and decoding this vector displacement into a correction for the tool of interest (or each tool) which aims to remove these differences such that they perform more similarly (i.e., all show similar performance to the reference tool).

In a specific embodiment, first monitoring data is obtained from recurrent monitoring; e.g., by a monitor wafer of a type described in relation to FIG. 5. The data may comprise overlay or other parameter of interest measurements performed on the monitor wafer for baseline monitoring and stability control, and relating to multiple scanners. As such, the lithographic matching performance being evaluated may comprise overlay matching performance, and the monitoring data may comprise a grid of overlay measurements (e.g., described as a wafer map or fingerprint). The monitoring data may be obtained by measuring one or more monitoring substrates periodically processed on the respective lithographic apparatus or other tool. The monitoring data may, for example, comprise one or both of inter-field data corresponding to a plurality of lithographic exposure fields and intra-field data corresponding to a lithographic exposure field.

Optionally, the monitoring data may comprise other scanner context: such as alignment data, leveling data, temperature data, etc., may also be included. The transformation within the latent space may transform each scanner to the reference or average scanner. The output may then comprise a machine matching overlay correction set (e.g., comprising corrections for each scanner).

Knowledge of the existing machine matching approaches and associated models can be included in the encoder-network (e.g., averaging over previous runs, etc., for some or all parameters and functionality). Differences between tools can be investigated by projecting the latent space vector back onto measurement/machine parameters.

The measurement data is mapped onto vectors in the latent space such that basic mathematical operations can be performed on the vectors in the latent space, e.g. add, subtract. Therefore certain reference state(s) can be subtracted (or added) to a data-set. Also, other operations can be performed based on properties of the dataset, e.g. to subtract reference data (reference state(s)) relating to a first type of scanner and add reference data relating to a second type of scanner. The trained network can capture unknown error sources and adapt to new scanner capabilities, and provides easier correction for cross-platform matching.

In practice, when performing machine matching, it can be challenging to distinguish between the part that can be fixed by APC/scanner calibration and the scanner-to-scanner differences, which lead to increased overlay and/or focus. This is because, though the statistical properties of the scanner-to-scanner differences appear to be within small/limited ranges (in terms of mean and standard deviation), the impact of non-linear effects on the fingerprint differences can be significant.

In a third main embodiment therefore, a nonlinear data-driven machine matching method is proposed. The method comprises identifying the latent structure of the monitoring data relating to the scanners (e.g., as obtained from monitor wafers as already described) by using nonlinear dimensionality reduction techniques, such as clustering and manifold learning techniques. Once clustered, first groups or clusters are identified within the monitoring data which share similar but not identical shapes. These first groups each then have their dominant fingerprints removed as these fingerprints may be corrected using the aforementioned APC correction loops, for example. What remains is processed monitoring data (fingerprints) relating to nanometer-scale effects idiosyncratic to each individual machine/chuck/track etc. As such, this transformed monitoring data can be used to reveal the ideal/calibrated performance of the scanners. By performing a second nonlinear dimensionality reduction (e.g., using clustering and manifold learning techniques) on this processed monitoring data, a number of second groups (the final data groups) may be obtained. Each of these second groups or data groups can determine a proposed matching of the machines. The fact that the method is data driven means that there are no assumptions necessary and the determined matching is dependent only on measured data and performance.

FIG. 11 is a flowchart describing such a method for matching (e.g., lithography) machines in such a way that their nanometer-scale differences are as small as possible. A monitoring dataset 1100 (e.g., overlay, focus or other parameter of interest data from monitoring wafers) is modeled 1110 using known or standard modeling techniques (e.g., using a 6 parameter or higher order or any other alignment model) to obtain a modeled dataset (e.g., fingerprint data). At step 1120, a first clustering and manifold learning step is performed on the fingerprint data and at step 1130 the common data per cluster or group is removed (e.g., the mean of each group is removed). At step 1140, a second clustering and manifold learning step is performed on the processed data, having had commonalities removed. At step 1150, matching machines (or components thereof, e.g., tracks/chucks etc.) are identified as those grouped together in the latent space defined by the previous step. A pattern classification or feature extraction step 1160 may be performed on the latent representation, (e.g., a principal component analysis, other component analysis or any pattern recognition and feature extraction algorithm) to identify and classify patterns and trends in the clusters. Each cluster may represent multiple machines with similar behavior, and this behavior can originate from several independent root causes. This last step 1160 can be used to find and identify these root causes/failure modes (e.g., thermal induced pattern, wafer load induced pattern) of observed behaviors within one cluster.

FIG. 12 illustrates the clustering and manifold learning steps in a simple 2D example. FIG. 12(a) is an example of the fingerprint data, and FIG. 12(b) shows the result of a clustering step, showing three main clusters or groups (each ringed on the Figure). FIG. 12(c) is a manifold representation of the data which can be used to identify a “continuous” structure of the latent process. This data can then be ordered to obtain the representation of FIG. 12(d) which describes the order of the data within clusters.

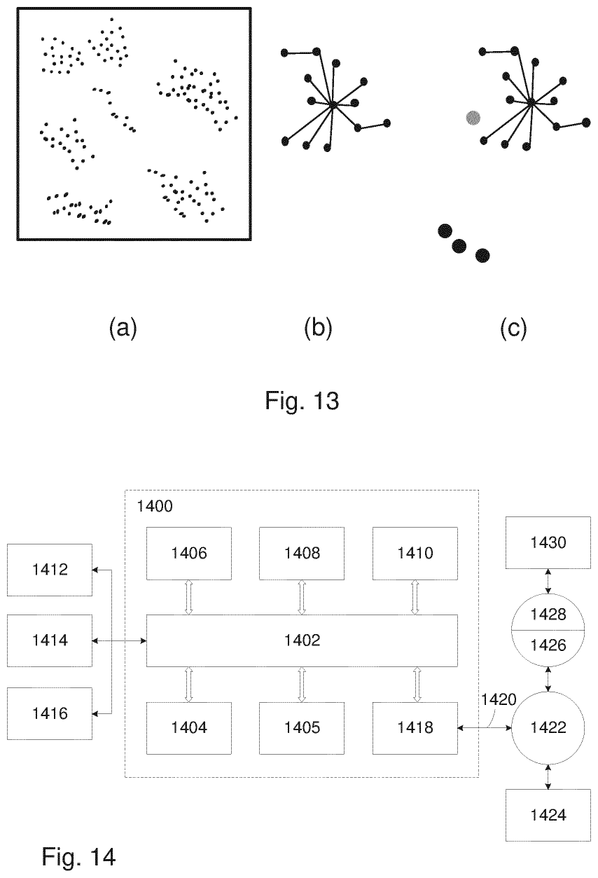

The basic methodology of this embodiment may also be used for production monitoring via monitoring wafers. FIG. 13 conceptually illustrates the basic concept. The aforementioned steps described by FIG. 11 may be used to compute/identify the latent structure of the monitoring data relating to multiple machines. FIG. 13(a) shows the result of such a method, where each point represents a monitor wafer. This represents a snapshot of how the machines perform in terms of monitor wafer shapes. FIG. 13(b) is an isolated snapshot of a cluster of interest, and comprises monitor wafers of specific machines/chucks/tracks; this snapshot can then be used as reference to check against for future wafers. If everything is under control any new/future wafer of the same origin should belong/identified as member of the current cluster and manifold. Such a future wafer is represented by the gray dot in FIG. 13(c) On the other hand, when new clusters are being formed, as indicated by the black dots in FIG. 13(c). This is indicative of a significant change in, for example, monitor wafer production and a flag may be raised accordingly when this occurs.

Note that the teachings herein (for all embodiments) can be expanded to any type of processing tool for which there may be a matching requirement (e.g., to replace an unavailable too) and or where the drift with respect to a reference is to be tracked and corrected for. Such tools, in addition to scanners (or steppers or any other lithography exposure tools), may comprises any metrology tools, polishing tools, etch tools/chambers, deposition tools, etc.

The methods described here may be used to build products which (1) tune scanners together with active control loops, (2) optimize wafer routing in production and/or (3) do scanner-to-process equipment matching.

It should be noted that although the description herein often refers to a (single) latent (or reduced feature) space, this should not be considered limiting. The principles described herein may be applied with and/or to any number of latent spaces. For example, the systems, methods, (metrology) apparatus, non-transitory computer readable media, etc., described herein may be configured such that a determination of the matching metric and/or correction may be based on one more data sets associated with multiple scanners and represented in a plurality of latent spaces (e.g. at least two).

The plurality of latent spaces may be used in series (e.g., for analyzing the data set(s) and/or making a first matching prediction, then a second, etc.), in parallel (e.g., for analyzing the data set(s) and/or making matching predictions simultaneously), and/or in other ways. Advantageously, individual latent spaces associated with a suitable model may be more robust compared to a single latent space. For example, separate latent spaces may be focused on specific properties of a dataset, e.g. one for retrieving a first matching metric related to overlay properties of the scanners of interest, another for scanner classification based on aberrations of the projection optics of said scanners of interest, etc. One combined latent space may be configured to capture all possibilities, while in the case of separate latent spaces, each individual latent space may be configured to (e.g., trained to) focus on a specific topic and/or aspect of a dataset. Individual latent spaces may potentially be simpler but be better at capturing information (e.g., when set up accordingly).

In some embodiments, the one or more latent spaces may comprise at least two latent spaces, a plurality of latent spaces, and/or other quantities of latent spaces, with individual latent spaces corresponding to different regimes of the model used in defining the latent spaces. The different regimes of the model may comprise an encoding regime (e.g., EN shown in FIG. 10), a decoding regime (e.g., DE shown in FIG. 10), a matching metric determination regime and a scanner correction determination regime (e.g., determination of one or more corrections to improve a quality of matching between scanners). In some embodiments, the different regimes may correspond to different operations performed by one or more models used in determining a parameter of interest (such as a matching metric or a correction). By way of a non-limiting example, in some embodiments, multiple latent spaces may be used in parallel, e.g., one for the image encoding and/or decoding, another for predicting the matching metric, another for correction settings (e.g., predicting or recommending scanner set points), etc. Individual latent spaces that correspond to different regimes may be more robust compared to a single latent space associated with multiple regimes.

In some embodiments, individual latent spaces may be associated with different independent parameters comprised within the data set(s) used as input (for example input ‘x’ as depicted in FIG. 10). Individual latent spaces that correspond to different independent parameters may also be more robust compared to a single latent space associated with multiple parameters. For example, in some embodiments, the present system(s) and method(s) may include or utilize a first latent space for matching of overlay between scanners, and a second separate latent space that deals with disturbances having an effect on imaging properties affecting dimensional properties of patterns produced by the scanners of interest. The first latent space may be configured to (e.g., trained to) perform the overlay matching or characterization, and independent of this first latent space, the second latent space may be configured to (e.g., trained to) deal with differences in imaging caused by tool specific properties. It should be noted that this is just one possible example, and is not intended to be limiting. Many other possible examples are contemplated.

FIG. 14 is a block diagram that illustrates a computer system 1400 that may assist in implementing the methods and flows disclosed herein. Computer system 1400 includes a bus 1402 or other communication mechanism for communicating information, and a processor 1404 (or multiple processors 1404 and 1405) coupled with bus 1402 for processing information. Computer system 1400 also includes a main memory 1406, such as a random access memory (RAM) or other dynamic storage device, coupled to bus 1402 for storing information and instructions to be executed by processor 1404. Main memory 1406 also may be used for storing temporary variables or other intermediate information during execution of instructions to be executed by processor 1404. Computer system 1400 further includes a read only memory (ROM) 1408 or other static storage device coupled to bus 1402 for storing static information and instructions for processor 1404. A storage device 1410, such as a magnetic disk or optical disk, is provided and coupled to bus 1402 for storing information and instructions.

Computer system 1400 may be coupled via bus 1402 to a display 1412, such as a cathode ray tube (CRT) or flat panel or touch panel display for displaying information to a computer user. An input device 1414, including alphanumeric and other keys, is coupled to bus 1402 for communicating information and command selections to processor 1404. Another type of user input device is cursor control 1416, such as a mouse, a trackball, or cursor direction keys for communicating direction information and command selections to processor 1404 and for controlling cursor movement on display 1412. This input device typically has two degrees of freedom in two axes, a first axis (e.g., x) and a second axis (e.g., y), that allows the device to specify positions in a plane. A touch panel (screen) display may also be used as an input device.

One or more of the methods as described herein may be performed by computer system 1400 in response to processor 1404 executing one or more sequences of one or more instructions contained in main memory 1406. Such instructions may be read into main memory 1406 from another computer-readable medium, such as storage device 1410. Execution of the sequences of instructions contained in main memory 1406 causes processor 1404 to perform the process steps described herein. One or more processors in a multi-processing arrangement may also be employed to execute the sequences of instructions contained in main memory 1406. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1404 for execution. Such a medium may take many forms, including but not limited to, non-volatile media, volatile media, and transmission media. Non-volatile media include, for example, optical or magnetic disks, such as storage device 1410. Volatile media include dynamic memory, such as main memory 1406. Transmission media include coaxial cables, copper wire and fiber optics, including the wires that comprise bus 1402. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1404 for execution. For example, the instructions may initially be borne on a magnetic disk of a remote computer. The remote computer can load the instructions into its dynamic memory and send the instructions over a telephone line using a modem. A modem local to computer system 1400 can receive the data on the telephone line and use an infrared transmitter to convert the data to an infrared signal. An infrared detector coupled to bus 1402 can receive the data carried in the infrared signal and place the data on bus 1402. Bus 1402 carries the data to main memory 1406, from which processor 1404 retrieves and executes the instructions. The instructions received by main memory 1406 may optionally be stored on storage device 1410 either before or after execution by processor 1404.

Computer system 1400 also preferably includes a communication interface 1418 coupled to bus 1402. Communication interface 1418 provides a two-way data communication coupling to a network link 1420 that is connected to a local network 1422. For example, communication interface 1418 may be an integrated services digital network (ISDN) card or a modem to provide a data communication connection to a corresponding type of telephone line. As another example, communication interface 1418 may be a local area network (LAN) card to provide a data communication connection to a compatible LAN. Wireless links may also be implemented. In any such implementation, communication interface 1418 sends and receives electrical, electromagnetic or optical signals that carry digital data streams representing various types of information.

Network link 1420 typically provides data communication through one or more networks to other data devices. For example, network link 1420 may provide a connection through local network 1422 to a host computer 1424 or to data equipment operated by an Internet Service Provider (ISP) 1426. ISP 1426 in turn provides data communication services through the worldwide packet data communication network, now commonly referred to as the “Internet” 1428. Local network 1422 and Internet 1428 both use electrical, electromagnetic or optical signals that carry digital data streams. The signals through the various networks and the signals on network link 1420 and through communication interface 1418, which carry the digital data to and from computer system 1400, are exemplary forms of carrier waves transporting the information.

Computer system 1400 may send messages and receive data, including program code, through the network(s), network link 1420, and communication interface 1418. In the Internet example, a server 1430 might transmit a requested code for an application program through Internet 1428, ISP 1426, local network 1422 and communication interface 1418. One such downloaded application may provide for one or more of the techniques described herein, for example. The received code may be executed by processor 1404 as it is received, and/or stored in storage device 1410, or other non-volatile storage for later execution. In this manner, computer system 1400 may obtain application code in the form of a carrier wave.

Embodiments may be implemented in a lithographic apparatus, such as described with reference to FIG. 1, comprising:
an illumination system configured to provide a projection beam of radiation;
a support structure configured to support a patterning device, the patterning device configured to pattern the projection beam according to a desired pattern;
a substrate table configured to hold a substrate;
a projection system configured the project the patterned beam onto a target portion of the substrate;
and
a processing unit configured to perform any of the methods described herein.

Embodiments may be implemented in any of the tools represented in a lithocell, such as described with reference to FIG. 2.

Embodiments may be implemented in a computer program product comprising machine readable instructions for causing a general-purpose data processing apparatus to perform the steps of a method as described.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). It is also to be noted that the term metrology apparatus or metrology system encompasses or may be substituted with the term inspection apparatus or inspection system. A metrology or inspection apparatus as disclosed herein may be used to detect defects on or within a substrate and/or defects of structures on a substrate. In such an embodiment, a characteristic of the structure on the substrate may relate to defects in the structure, the absence of a specific part of the structure, or the presence of an unwanted structure on the substrate, for example.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of physical systems such as structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of a physical structure may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

Further embodiments are disclosed in the list of numbered clauses below:
1. A method of determining matching performance between tools used in semiconductor manufacture, the method comprising:
   obtaining a plurality of data sets related to a plurality of tools,
   obtaining a representation of said data sets in a reduced space having a reduced dimensionality to obtain reduced data sets; and
   determining a matching metric and/or matching correction based on characterizing said reduced data sets in the reduced space.
2. A method according to clause 1, wherein each data set is related to a different respective tool.
3. A method according to clause 1 or 2, wherein the data sets relate to a variation of one or more tool and/or manufacturing parameters over time.
4. A method according to any preceding clause, wherein the data sets describe the parameters for a substrate over a full manufacturing process within one or more tools.
5. A method according to any preceding clause, wherein said representation comprises at least one model configured to represent the data sets in the reduced space, said at least one model comprising one or more functional models based on known physics related to a particular manufacturing step or process and the associated tool, and the method comprises determining one or more functional indicators from the one or more functional models and the plurality of data sets.
6. A method according to clause 5, wherein the one or more functional indicators describe a deviation of a parameter value from nominal behavior, said nominal behavior being derived from said known physics.
7. A method according to clause 5 or 6, wherein each of the one or more functional indicators is trained using one or more of: statistical technique, optimization, regression, or a machine learning technique.
8. A method according to any of clauses 5 to 7, comprising combining and/or aggregating the functional indicators per tool and/or per process to obtain a tool functional fingerprint comprising a model which functionality defines the performance of the tool.
9. A method according to clause 8, wherein a machine learning technique is applied to the functional indicators to identify the tool functional fingerprint.
10. A method according to any of clauses 5 to 9, comprising determining which functional indicators are more relevant for said matching metric.
11. A method according to any of clauses 5 to 10, comprising ranking said functional indicators or tool functional fingerprints according to said matching metric.
12. A method according to any of clauses 5 to 11, wherein said ranking comprises ranking said functional indicators or tool functional fingerprints according to a similarity to a tool of interest or other reference.
13. A method according to any of clauses 5 to 12, comprising applying a clustering algorithm to said functional indicators or tool functional fingerprints, to determine the matching metric.
14. A method according to any of clauses 5 to 13, comprising applying a decision model which outputs a value for each of one or more categorical indicators based on parameter data, to parameter data relating to one or more tools being matched, each of the one or more categorical indicators being indicative of a quality of the manufacturing process; and deciding or validating whether a machine is well matched based on the categorical indicator.
15. A method according to clause 14, comprising using the decision model trained for a first tool to predict the performance categorically based on parameter data of a second tool so as to evaluate whether the first tool and second tool are well matched.
16. A method according to clause 14 or 15, wherein each of the one or more categorical indicators is derived from said one or more functional indicators by categorizing the functional indictors according to one or more applied and/or learned threshold values to the one or more functional indicators.
17. A method according to clause 1 or 2, wherein said representation comprises an encoder-decoder network model operable to encode the data sets into and decode the data sets back from, said reduced space representation.
18. A method according to clause 17, wherein said reduced space representation is a latent space comprising a vector representation and the matching metric is based on a vector comparison.
19. A method according to clause 18, comprising:
   choosing a reference within the latent space, determine the vector displacement of one or more of said plurality of tools to this reference; and
   decoding this vector displacement into a correction for one or more of said plurality of tools, each correction making its respective tool perform more similarly to the reference.
20. A method according to any of clauses 17 to 19, comprising ranking the tools according to their proximity in the latent space to a tool of interest or other reference.
21. A method according to any of clauses 17 to 20, comprising subtracting reference data relating to a first type of tool and adding reference data relating to a second type of tool within the latent space, to match a tool of the first type with a tool of the second type.
22. A method according to any of clauses 17 to 21, comprising training the model on historic scanner data sets for multiple tools and types of tools.
23. A method according to clause 1 or 2, wherein said step of obtain a representation of said data sets in a reduced space comprises performing one or more nonlinear dimensionality reduction techniques on said data sets.
24. A method according to clause 23, wherein said one or more nonlinear dimensionality reduction technique comprises performing clustering and manifold learning on said datasets to group said data sets into data groups; and determining matched tools as those belonging to a common data group.
25. A method according to clause 24, comprising:
   performing a first clustering and manifold learning step to obtain first groups;
   removing common and/or dominant data patterns per first groups to obtain processed data sets; and
   performing a second clustering and manifold learning step on said processed data sets to obtain said data groups.
26. A method according to clause 24 or 25, further comprising performing a pattern classification and/or feature classification step on one or more of the data groups so as to identify a root cause or failure mode.
27. A method according to any of clauses 24 to 26, comprising performing production monitoring based on said reduced space; said method comprising, obtaining one or more further said data sets relating to an actual production process; referencing said one or more further said data sets in said reduced space to a corresponding said data group.
28. A method according to clause 27, comprising flagging a potential issue if said referencing is indicative of a significant change between said one or more further said data sets with respect to said corresponding said data group.
29. A method according to any of clauses 17 to 28, wherein each of said data sets comprise monitoring data from recurrent monitoring for stability control of said plurality of tools.
30. A method according to clause 29, wherein the monitoring data comprises a grid of overlay or focus measurements.
31. A method according to clause 29 or 30 wherein the monitoring data are obtained by measuring one or more monitoring substrates periodically processed on the respective tool.
32. A method according to clause 29, 30 or 31, wherein the monitoring data comprises other tool context, such as one or more of alignment data, leveling data, temperature data.
33. A method according to any preceding clause, wherein said plurality of tools comprises one or more of: lithography exposure tools, metrology tools, polishing tools, etch tools/chambers and deposition tools.
34. A semiconductor manufacturing process comprising a method for determining lithographic matching performance according to the method of any preceding clause.
35. A computer program product comprising machine readable instructions for causing a general-purpose data processing apparatus to perform the steps of a method according to any of clauses 1 to 33.
36. A processing unit and storage comprising the computer program product of clause 35.
37. A lithographic apparatus comprising:
   an illumination system configured to provide a projection beam of radiation;
   a support structure configured to support a patterning device, the patterning device configured to pattern the projection beam according to a desired pattern;
   a substrate table configured to hold a substrate;
   a projection system configured the project the patterned beam onto a target portion of the substrate; and
   the processing unit of clause 36.
38. A lithographic cell comprising the lithographic apparatus of clause 37.
39. A non-transitory computer readable medium having instructions thereon, the instructions when executed by a computer causing the computer to:
   obtain a plurality of data sets related to a plurality of tools used in a semiconductor manufacturing process;
   obtain a representation of said data sets in a reduced space having a reduced dimensionality to obtain reduced data sets; and
   determine a matching metric and/or matching correction based on characterizing said reduced data sets in the reduced space.
40. The medium of clause 39, wherein the reduced space comprises one or more latent spaces.
41. The medium of clause 40, wherein the one or more latent spaces comprise at least two latent spaces.
42. The medium of clauses 40 or 41, wherein the one or more latent spaces comprise a plurality of latent spaces, with individual latent spaces of the plurality of latent spaces corresponding to different regimes of a model used in defining said one or more latent spaces.
43. The medium of clause 42, wherein the different regimes of the model comprise an encoding regime and a decoding regime.
44. The medium of clause 43, wherein the different regimes of the model further comprise a matching metric determination regime and/or a tool correction determination regime.
45. The medium of any of clauses 40-44, wherein the one or more latent spaces comprise at least two latent spaces associated with different independent parameters comprised within the plurality of data sets.
46. The medium of clause 45, wherein the different independent parameters comprise an overlay related parameter and an imaging related parameter.
47. The method of any of clauses 1-33, wherein the reduced space comprises one or more latent spaces.
48. The method of clause 47, wherein the one or more latent spaces comprise at least two latent spaces.
49. The method of clause 47 or 48, wherein the one or more latent spaces comprise a plurality of latent spaces, with individual latent spaces of the plurality of latent spaces corresponding to different regimes of a model used in defining said one or more latent spaces.
50. The method of clause 49, wherein the different regimes of the model comprise an encoding regime and a decoding regime.
51. The method of clause 50, wherein the different regimes of the model further comprise a matching metric determination regime and/or a tool correction determination regime.
52. The method of any of clauses 47-51, wherein the one or more latent spaces comprise at least two latent spaces associated with different independent parameters comprised within the plurality of data sets.
53. The method of clause 52, wherein the different independent parameters comprise an overlay related parameter and an imaging related parameter.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A method of determining matching performance between tools used in semiconductor manufacturing, the method comprising:
obtaining a plurality of data sets related to a plurality of tools,
obtaining a representation of the data sets in a reduced space having a reduced dimensionality to obtain reduced data sets, the obtaining the representation comprising:
performing one or more nonlinear dimensionality reduction techniques on the data sets, or
using an encoder-decoder network model to encode the data sets into and decode the data sets back from, the reduced space representation; and
determining a matching metric and/or matching correction based on characterizing the said reduced data sets in the reduced space.

2. The method as claimed in claim 1, wherein each data set is related to a different respective tool.

3. The method as claimed in claim 1, wherein the data sets relate to a variation of one or more tool and/or manufacturing parameters over time.

4.-9. (canceled)

10. The method as claimed in claim 1, comprising using the encoder-decoder network model to encode the data sets into and decode the data sets back from, the reduced space representation.

11. The method as claimed in claim 1, comprising performing one or more nonlinear dimensionality reduction techniques on the data sets, wherein the one or more nonlinear dimensionality reduction techniques comprises performing clustering and manifold learning on the datasets to group the data sets into data groups and determining matched tools as those belonging to a common data group.

12. A non-transitory computer-readable medium having instructions therein, the instructions, when executed by a computer system, configured to cause the computer system to at least:
obtain a plurality of data sets related to a plurality of tools used in a semiconductor manufacturing process;
obtain a representation of the data sets in a reduced space having a reduced dimensionality to obtain reduced data sets, wherein the obtaining of the representation comprises:
performance of one or more nonlinear dimensionality reduction techniques on the data sets, or
use of an encoder-decoder network model to encode the data sets into and decode the data sets back from, the reduced space representation; and
determine a matching metric and/or matching correction based on characterizing the reduced data sets in the reduced space.

13. The medium of claim 12, wherein the reduced space comprises a plurality of latent spaces, with individual latent spaces of the plurality of latent spaces corresponding to different regimes of a model used in defining the said reduced space.

14. The medium of claim 13, wherein the different regimes of the model further comprise a matching metric determination regime and/or a tool correction determination regime.

15. The medium of claim 14, wherein the one or more latent spaces comprise at least two latent spaces associated with different independent parameters comprised within the plurality of data sets.

16. The medium of claim 12, wherein the representation is a latent space comprising a vector representation and the matching metric is based on a vector comparison.

17. The medium of claim 16, wherein the instructions are further configured to cause the computer system to:
choose a reference within the latent space;
determine the vector displacement of one or more of the plurality of tools to this reference; and
decode this vector displacement into a correction for one or more of the plurality of tools, each correction making its respective tool perform more similarly to the reference.

18. The medium of claim 12, wherein the instructions are configured to cause the computer system to use the encoder-decoder network model to encode the data sets into and decode the data sets back from, the reduced space representation.

19. The medium of claim 12, wherein each data set is related to a different respective tool.

20. The medium of claim 12, wherein the data sets relate to a variation of one or more tool and/or manufacturing parameters over time.

21. The method of claim 1, wherein the reduced space representation is a latent space comprising a vector representation and the matching metric is based on a vector comparison.

22. The method of claim 21, further comprising:
choosing a reference within the latent space;
determining the vector displacement of one or more of the plurality of tools to this reference; and
decoding this vector displacement into a correction for one or more of the plurality of tools, each correction making its respective tool perform more similarly to the reference.

23. The method of claim 21, further comprising ranking the tools according to their proximity in the latent space to a tool of interest or other reference.

24. The method of claim 21, further comprising subtracting reference data relating to a first type of tool and adding reference data relating to a second type of tool within the latent space, to match a tool of the first type with a tool of the second type.

25. The method of claim 21, further comprising training the model on historic scanner data sets for multiple tools and types of tools.

26. The method of claim 11, further comprising:
performing a first clustering and manifold learning step to obtain first groups;
removing common and/or dominant data patterns per the first groups to obtain processed data sets; and
performing a second clustering and manifold learning step on the processed data sets to obtain the data groups.
